(19) United States
(12) Patent Application Publication
(10) Pub. No.: US 2024/0339331 A1
(43) Pub. Date: Oct. 10, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chung-Fu Chang, Tainan City (TW); Guang-Yu Lo, New Taipei City (TW); Chun-Tsen Lu, Tainan City (TW)

(73) Assignee: UNITED MICROELECTRONICS CORP., Hsin-Chu City (TW)

(21) Appl. No.: 18/143,076

(22) Filed: May 4, 2023

(30) Foreign Application Priority Data
Apr. 7, 2023 (TW) 112112979

(51) Int. Cl. H01L 21/311; H01L 21/02; H01L 21/308; H01L 29/78

(52) U.S. Cl. CPC H01L 21/31144; H01L 21/02123; H01L 21/308; H01L 29/785; H01L 29/41791

(57) ABSTRACT

A method for fabricating a semiconductor device includes the steps of first providing a substrate comprising a medium-voltage (MV) region and a low-voltage (LV) region, forming a first gate structure and a second gate structure on the MV region and a second gate structure on the LV region, forming a patterned mask on the MV region as the patterned mask covers the first gate structure and the second gate structure and exposes the substrate between the first gate structure and the second gate structure, and then forming a first epitaxial layer between the first gate structure and the second gate structure.

### BACKGROUND OF THE INVENTION

### 1. Field of the Invention

The invention relates to a method for fabricating semiconductor device, and more particularly to a method of using patterned mask to form epitaxial layer on medium-voltage (MV) region.

### 2. Description of the Prior Art

In current semiconductor processing, controllers, memories, circuits of low-voltage operation and power devices of high-voltage operation are largely integrated into a single chip to achieve a single-chip system. The power device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease the integration of high-voltage devices and FinFET devices start to face numerous challenges such as current leakage and control of breakdown voltage. Hence, how to improve the current fabrication for improving performance of the device has become an important task in this field.

### SUMMARY OF THE INVENTION

According to an embodiment of the present invention, a method for fabricating a semiconductor device includes the steps of first providing a substrate comprising a medium-voltage (MV) region and a low-voltage (LV) region, forming a first gate structure and a second gate structure on the MV region and a second gate structure on the LV region, forming a patterned mask on the MV region as the patterned mask covers the first gate structure and the second gate structure and exposes the substrate between the first gate structure and the second gate structure, and then forming a first epitaxial layer between the first gate structure and the second gate structure.

According to another aspect of the present invention, a semiconductor device includes a substrate having a medium-voltage (MV) region and a low-voltage (LV) region, a first gate structure on the MV region, and a first epitaxial layer adjacent to the first gate structure. Preferably, the first gate structure includes a first gate dielectric layer on the substrate and a first gate electrode on the first gate dielectric layer, in which the first gate dielectric layer includes a curve.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a semiconductor device according to an embodiment of the present invention.

### DETAILED DESCRIPTION

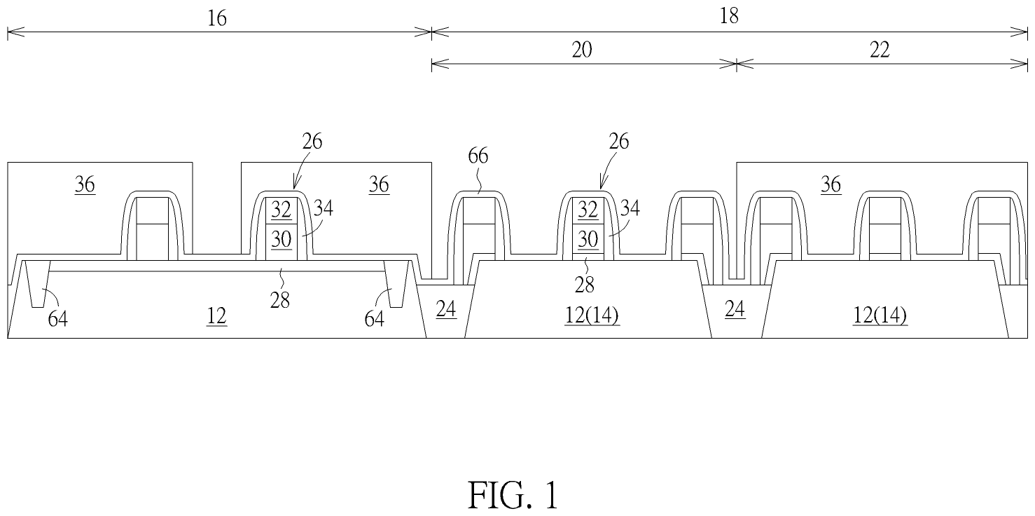

Referring to FIGS. 1-5, FIGS. 1-5 illustrate a method for fabricating a semiconductor device according to an embodiment of the present invention. As shown in FIG. 1, a substrate 12, such as a silicon substrate or silicon-on-insulator (SOI) substrate is first provided and three or more transistor regions including a high-voltage (HV) region (not shown), a medium-voltage (MV) region, and a low-voltage (LV) region are defined on the substrate 12, in which the LV region 18 further includes a first transistor region such as a NMOS region 20 and a second transistor region such as a PMOS region 22.

In this embodiment, the MV region 16 and the first transistor region such as the NMOS region 20 preferably include same conductive type. Nevertheless, the MV region 16 and the second transistor such as the PMOS region 22 could also have same conductive according to other embodiment of the present invention. Moreover, it would also be desirable to form well regions such as deep p-well or deep n-well on each of the regions through ion implantation process depending on the demand of the process.

Next, a plurality of fin-shaped structures 14 are formed on the substrate 12 of the LV region 18 while no fin-shaped structures are formed on the MV region 16. Preferably, planar devices will be fabricated on the MV region 16 and a shallow trench isolation (STI) 64 is disposed on the MV region 16 to separate the MV region 16 from adjacent areas. Preferably, the fin-shaped structures 14 of this embodiment could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 14 could also be obtained by first forming a patterned mask (not shown) on the substrate, 12, and through an etching process, the pattern of the patterned mask is transferred to the substrate 12 to form the fin-shaped structures 14. Moreover, the formation of the fin-shaped structures 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures 14. These approaches for forming fin-shaped structure are all within the scope of the present invention.

Next, another STI 24 is formed to surround the fin-shaped structures 14. In this embodiment, the formation of the STI 24 could be accomplished by first conducting a flowable chemical vapor deposition (FCVD) process to form an insulating layer made of silicon oxide on the substrate 12 and the fin-shaped structures 14, and then conducting a planarizing process such as chemical mechanical polishing (CMP) process along with etching to remove part of the insulating layer. The remaining insulating layer 32 having a top surface slightly lower than the top surface of the fin-shaped structures 14 then forms the STI 24.

Next, at least a dummy gate or gate structure 26 is formed on the substrate 12. In this embodiment, the formation of the gate structures 26 could be accomplished by a gate first process, a high-k first approach from gate last process, or a high-k last approach from gate last process. Since this embodiment pertains to a high-k last approach, a gate dielectric layer 28 or interfacial layer made of silicon oxide, a gate material layer 30 made of polysilicon, and a selective hard mask 32 could be formed sequentially on the substrate 12, and a pattern transfer process is then conducted by using a patterned resist (not shown) as mask to remove part of the hard mask 32, part of the gate material layer 30, and even part of the gate dielectric layer 28 through single or multiple etching processes. After stripping the patterned resist, gate structures 26 each composed of a gate dielectric layer 28, a patterned gate material layer 30, and a patterned hard mask 32 are formed on the substrate 12.

It should be noted that the gate dielectric layers 28 on the MV region 16 and LV region 18 could have different thicknesses and could be fabricated on different stages of the process. For instance, it would be desirable to first form a gate dielectric layer 28 used for MV device on the substrate 12 of the MV region 16 and then form a gate dielectric layer 28 used for LV device on the substrate 12 of the LV region 18, in which the thickness of the gate dielectric layer 28 on the LV region 18 is less than the thickness of the gate dielectric layer 28 on the MV region 16. Next, a gate material layer 30 made of polysilicon and a hard mask 32 are formed on the MV region 16 and LV region 18 and then the hard mask 32 and the gate material layer 30 are patterned to form gate structure 26 on each of the regions as disclosed previously.

Next, at least a spacer 34 is formed on sidewalls of the gate structure 18. In this embodiment, the spacers 34 could be a single spacer or a composite spacer, in which the spacer 34 could further include an offset spacer (not shown) and a main spacer (not shown). The offset spacer and the main spacer are preferably made of different materials while the offset spacer and main spacer could all be selected from the group consisting of SiO₂, SiN, SiON, and SiCN, but not limited thereto.

Next, a selective hard mask 66 made of silicon oxide or silicon nitride could be formed on the substrate 12 of the MV region 16 and LV region 18 to cover the gate structures 26 and then a patterned mask 36 such as patterned resist is formed on the MV region 16 and part of the LV region 18 such as the PMOS region 22. Preferably, the patterned mask 36 is disposed to cover the entire PMOS region 22 and the gate structures 26 on the MV region 16 while exposing the substrate 12 or hard mask 66 between two adjacent gate structures 26 on the MV region 16 as well as the entire NMOS region 20. In other words, in contrast to all the surface of the substrate 12 or hard mask 66 is expose between gate structures 26 on the NMOS region 20 of the LV region 18, only part the substrate 12 surface or hard mask 66 surface is exposed between gate structures 26 on the MV region 16. The exposed region is preferably used to form epitaxial layers in the later process.

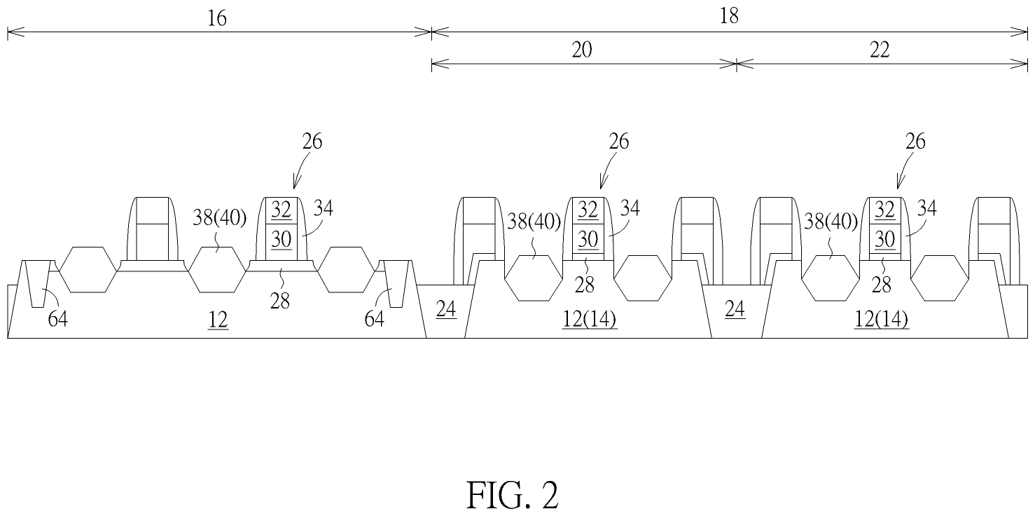

Next, as shown in FIG. 2, one or more dry etching and/or wet etching process is conducted by using the patterned mask 36 as mask to remove the hard mask 66 and the substrate 12 not covered by the patterned mask 36 for forming recesses (not shown) in the substrate 12 adjacent to two sides of the gate structure 26. After stripping the patterned mask 36, a selective epitaxial growth (SEG) process is conducted to form epitaxial layers 38 in the recesses on the MV region 16 and NMOS region 20, and then the hard mask 66 is removed thereafter.

Next, another patterned mask (not shown) is formed on the entire MV region 16 and the NMOS region 20 of LV region 18 while exposing the PMOS region 22, and then the formation of the aforementioned epitaxial layers 38 could be repeated by using the patterned mask on the MV region 16 and NMOS region 18 to conduct one or more dry etching and/or wet etching process to remove the substrate 12 on the PMOS region 22 for forming recesses (not shown) adjacent to two sides of the gate structures 26 on the PMOS region 22. Next, a SEG process conducted to form epitaxial layers 38 in the recesses on the PMOS region 22.

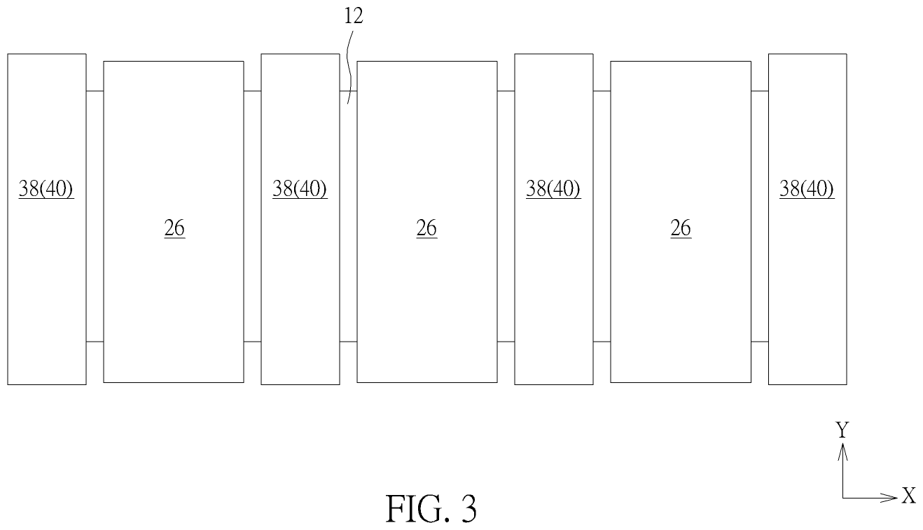

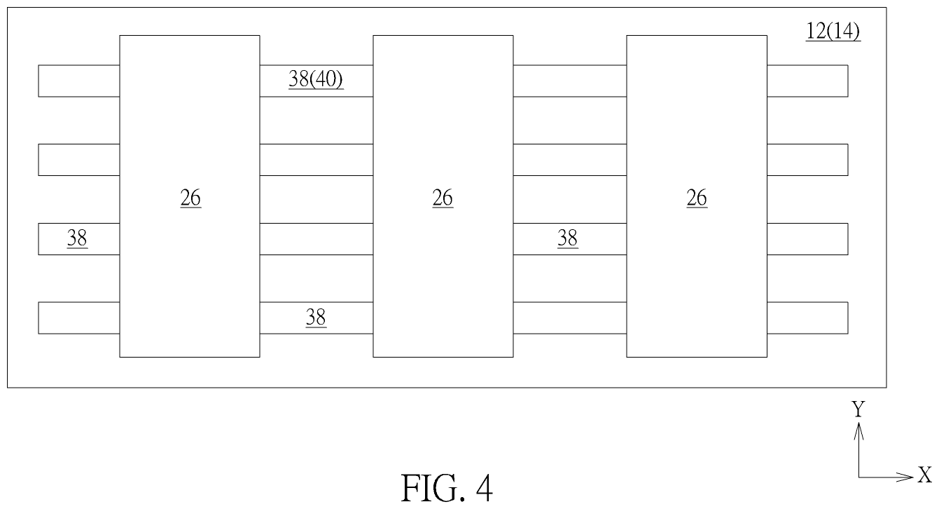

Referring to FIGS. 3-4, FIG. 3 illustrates a top view for forming epitaxial layers 38 on the MV region 16 according to the aforementioned process and FIG. 4 illustrates a top view for forming epitaxial layers 38 on the NMOS region 20 of the LV region 18 according to the aforementioned process. As shown in FIG. 3, the gate structures 26 on the MV region 16 are disposed extending along Y-direction and the epitaxial layers 38 fabricated according to the aforementioned process are also disposed extending along the Y-direction adjacent to two sides of the gate structures 26, in which gaps are formed between two sidewalls or edges of the epitaxial layers 38 and the gate structures 26 so that the edges of the epitaxial layers 38 and gate structures 26 do not overlap or contact each other. In contrast to the epitaxial layers 38 and the gate structures 26 on the MV region 16 are extending along same direction, the epitaxial layers 38 on the LV region 18 as shown in FIG. 4 are extending along a direction perpendicular to the gate structures 26 and adjacent to two sides of the gate structures 26. In other words, the epitaxial layers 38 are extending along X-direction adjacent to two sides of the gate structures 26 and between adjacent gate structures 26 while the edges of the epitaxial layers 38 preferably contact and overlap edges of the gate structures 26.

In this embodiment, the epitaxial layers 38 preferably share substantially same cross-section shape with the recess. For instance, the cross-section of each of the epitaxial layers 38 could also include a circle, a hexagon, or an octagon depending on the demand of the product. In this embodiment, the epitaxial layers 38 could also be formed to include different materials depending on the type of transistor being fabricated. For instance, if the MOS transistor being fabricated were to be a PMOS transistor, the epitaxial layers 38 could be made of material including but not limited to for example SiGe, SiGeB, or SiGeSn. If the MOS transistor being fabricated were to be a NMOS transistor, the epitaxial layers 38 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 38 is preferred to have less or no germanium atom at all to facilitate the formation of silicide afterwards.

According to an embodiment of the present invention, one or more ion implantation process could be conducted to form a source/drain region 40 in part or all of the epitaxial layer 38. According to another embodiment of the present invention, the source/drain region 40 could also be formed insituly during the SEG process. For instance, the source/drain region 40 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain region 40. Moreover, the dopants within the source/drain region 40 could also be formed with a gradient, which is also within the scope of the present invention.

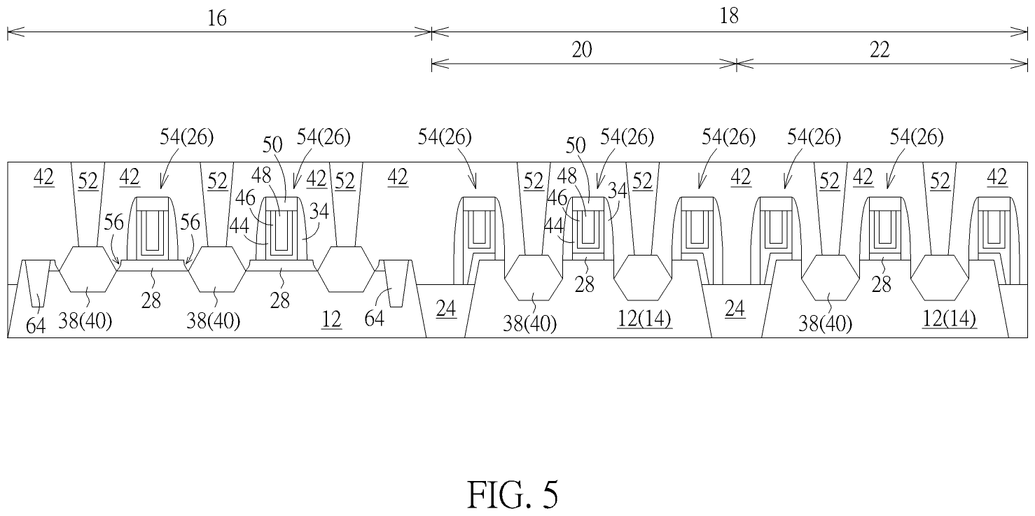

Next, as shown in FIG. 5, a selective contact etch stop layer (CESL) (not shown) could be formed on the substrate 12 surface to cover the gate structures 26 on the HV region, MV region 16, and LV region 18, and an interlayer dielectric (ILD) layer 42 is formed on the CESL afterwards. Next, a planarizing process such as a chemical mechanical polishing (CMP) process is conducted to remove part of the ILD layer 42 and part of the CESL so that the top surfaces of the hard mask 32 and ILD layer 42 are coplanar.

Next, a replacement metal gate (RMG) process is conducted to transform the gate structures 26 the HV region, MV region 16, and LV region 18 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the hard masks 32 and the gate material layers 30 from gate structures 26 for forming recesses (not shown) in the ILD layer 42. Next, a high-k dielectric layer 44, a work function metal layer 46, and a low resistance metal layer 48 are formed in the recesses, and a planarizing process such as CMP is conducted to remove part of low resistance metal layer 48, part of work function metal layer 46, and part of high-k dielectric layer 44 to form metal gates. Preferably, the high-k dielectric layer 44, the work function metal layer 46, and the low resistance metal layer 48 altogether constitute the gate electrode 54 of each of the transistors or devices.

In this embodiment, the high-k dielectric layer 44 is preferably selected from dielectric materials having dielectric constant (k value) larger than 4. For instance, the high-k dielectric layer 46 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 46 is formed for tuning the work function of the metal gate in accordance with the conductivity of the device. For an NMOS transistor, the work function metal layer 46 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 46 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 46 and the low resistance metal layer 48 may include titanium (Ti), titanium nitride (TiN), tantalum (Ta) or tantalum nitride (TaN). Furthermore, the material of the low-resistance metal layer 48 may include copper (Cu), aluminum (Al), titanium aluminum (TiAl), cobalt tungsten phosphide (CoWP) or any combination thereof. Since the transformation of dummy gates into metal gates through RMG process is well known to those skilled in the art, the details of which are not explained herein for the sake of brevity. Next, part of the high-k dielectric layer 44, part of the work function metal layer 46, and part of the low resistance metal layer 48 are removed to form recesses (not shown), and a hard mask 50 is formed into each of the recesses so that the top surfaces of the hard masks 50 and the ILD layer 42 are coplanar. Preferably the hard masks 50 could include SiO₂, SiN, SION, SiCN, or combination thereof.

Next, a photo-etching process is conducted by using a patterned mask (not shown) as mask to remove part of the ILD layer 42 and part of the CESL adjacent to the gate structures 26 for forming contact holes (not shown) exposing the source/drain regions 40 underneath. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 52 electrically connecting the source/drain regions 40. This completes the fabrication of a semiconductor device according to an embodiment of the present invention.

Referring to FIG. 5, FIG. 5 illustrates a structural view of a semiconductor device according to an embodiment of the present invention. As shown in FIG. 5, the semiconductor device includes at least a MV device or MV transistor disposed on the MV region 16 and a LV device of LV transistor disposed on the NMOS region 20 and PMOS region 22 of the LV region 18.

Preferably, each of the MV transistors on the MV region 16 includes a gate structure 26 disposed on the substrate 12 and an epitaxial layer 38 in the substrate 12 adjacent to the gate structure 26. It should be noted that even though the epitaxial layer 38 is disposed in the substrate 12 adjacent to two sides of the two gate structures 26, according to other embodiment of the present invention it would also be desirable to form more than two such as three, four, or even five gate structures 26 and epitaxial layers 38 in the substrate 12 adjacent to two sides of each of the gate structures 38, which is also within the scope of the present invention.

Preferably, each of the gate structures 26 includes a gate dielectric layer 28 disposed on the substrate 12 and a gate electrode 54 disposed on the gate dielectric layer 28. It should be noted that since the aforementioned patterned mask 36 is disposed on the gate structures 26 and part of the substrate 12 adjacent to two sides of the gate structures 26 on the MV region 16 during formation of the epitaxial layers 38, the etching process conducted afterwards along sidewalls of the patterned mask 36 would remove the gate dielectric layer 28 and the substrate 12 to form recesses and at the time form curves 56 or curved surfaces on sidewalls of the gate dielectric layer 38 on the MV region 16. Preferably, the bottom surface or width of the bottom surface of the gate dielectric layer 28 on the MV region 12 would be greater than the top surface or width of the top surface of the gate dielectric layer 28 and an angle included by the top surface of the substrate 12 and the curves 56 is less than 90 degrees or most preferably between 40 to 80 degrees.

Similar to the gate structures 26 on the MV region 16, each of the gate structures 26 on the LV region 18 also includes a gate dielectric layer 28 on the substrate 12 and a gate electrode 54 disposed on the gate dielectric layer 28. In contrast to the two sidewalls of the gate dielectric layer 28 on the MV region 16 having curves 56 or curved surfaces, the gate dielectric layer 28 on the LV region 18 whether on the NMOS region 20 or PMOS region 22 are not exposed during the formation of recesses for forming epitaxial layers 38, hence the two sidewalls of each of the gate dielectric layer 28 on the LV region 18 all include vertical and planar surfaces. In other words, the bottom surface or width of the bottom surface of the gate dielectric layer 28 on the LV region 18 is equal to the top surface of width of the top surface of the gate dielectric layer 28 and the angle included by the top surface of the substrate 12 and the vertical surface of the gate dielectric layer 28 on the LV region 18 is equal to 90 degrees.

Overall, during formation of epitaxial layers on the MV region and LV region, the present invention first forms a patterned mask 36 to cover part of the MV region in particular the gate structures and part of the substrate surface adjacent to the gate structures and expose the substrate surface between gate structures not covered by the patterned mask, conducts an etching process along sidewalls of the patterned mask to form recesses adjacent to the gate structures, and then forms epitaxial layers in the recesses. By using this approach to form epitaxial layers on the MV region, it would be desirable to resolve issues such as loss of epitaxial layers and improve performance of the device substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate comprising a medium-voltage (MV) region and a low-voltage (LV) region;
forming a first gate structure and a second gate structure on the MV region and a second gate structure on the LV region;
forming a patterned mask on the MV region, wherein the patterned mask covers the first gate structure and the second gate structure and exposes the substrate between the first gate structure and the second gate structure; and
forming a first epitaxial layer between the first gate structure and the second gate structure.

2. The method of claim 1, wherein the LV region comprises a first transistor region and a second transistor region, the method comprising:
forming a third gate structure on the first transistor region and a fourth gate structure on the second transistor region;
forming the patterned mask on the MV region and the second transistor region;
forming the first epitaxial layer on the MV region and a second epitaxial layer adjacent to the third gate structure; and
forming a third epitaxial layer adjacent to the fourth gate structure.

3. The method of claim 2, wherein the patterned mask covers the MV region and the second transistor region while exposing the first transistor region.

4. The method of claim 2, wherein the patterned mask covers the second transistor region completely.

5. The method of claim 2, wherein the first epitaxial layer and the second epitaxial layer comprise same conductive type.

6. The method of claim 2, wherein the first epitaxial layer and the third epitaxial layer comprise different conductive type.

7. The method of claim 2, wherein the first gate structure comprises:
a first gate dielectric layer on the substrate, wherein a sidewall of the first gate dielectric layer comprises a curve; and
a first gate electrode on the first gate dielectric layer.

8. The method of claim 7, wherein an angle included by a top surface of the substrate and the curve is less than 90 degrees.

9. The method of claim 7, wherein a bottom surface of the first gate dielectric layer is greater than a top surface of the first gate dielectric layer.

10. The method of claim 2, wherein the third gate structure comprises:
a third gate dielectric layer on the substrate, wherein a sidewall of the third gate dielectric layer comprises a vertical surface; and
a third gate electrode on the third gate dielectric layer.

11. The method of claim 10, wherein an angle included by a top surface of the substrate and the vertical surface is equal to 90.

12. The method of claim 10, wherein a bottom surface of the third gate dielectric layer is equal to a top surface of the third gate dielectric layer.

13. A semiconductor device, comprising:
a substrate comprising a medium-voltage (MV) region and a low-voltage (LV) region; a first gate structure on the MV region, wherein the first gate structure comprises:
a first gate dielectric layer on the substrate, wherein the first gate dielectric layer comprises a curve;
a first gate electrode on the first gate dielectric layer; and
a first epitaxial layer adjacent to the first gate structure.

14. The semiconductor device of claim 13, wherein an angle included by a top surface of the substrate and the curve is less than 90 degrees.

15. The semiconductor device of claim 13, wherein a bottom surface of the first gate dielectric layer is greater than a top surface of the first gate dielectric layer.

16. The semiconductor device of claim 13, further comprising:
a second gate structure on the LV region, wherein the second gate structure comprises:
a second gate dielectric layer on the substrate, wherein a sidewall of the second gate dielectric layer comprises a vertical surface; and
a second gate electrode on the second gate dielectric layer; and
a second epitaxial layer adjacent to the second gate structure.

17. The semiconductor device of claim 16, wherein an angle included by a top surface of the substrate and the vertical surface is equal to 90.

18. The semiconductor device of claim 16, wherein a bottom surface of the second gate dielectric layer is equal to a top surface of the second gate dielectric layer.
